(19) United States
(12) Patent Application Publication
(10) Pub. No.: US 2025/0347994 A1
(43) Pub. Date: Nov. 13, 2025

(54) RESIST COMPOSITION AND PATTERN FORMATION METHOD USING THE SAME

(71) Applicant: Samsung Electronics Co., Ltd., Suwon-si (KR)

(72) Inventors: Haengdeog KOH, Suwon-si (KR); Yoonhyun KWAK, Suwon-si (KR); Beomseok KIM, Suwon-si (KR); Hyeran KIM, Suwon-si (KR); Sunyoung LEE, Suwon-si (KR); Jiyoun LEE, Suwon-si (KR); Changheon LEE, Suwon-si (KR); Jinwon JEON, Suwon-si (KR); Jungha CHAE, Suwon-si (KR); Minyoung HA, Suwon-si (KR)

(73) Assignee: Samsung Electronics Co., Ltd., Suwon-si (KR)

(21) Appl. No.: 18/921,412

(22) Filed: Oct. 21, 2024

(30) Foreign Application Priority Data
May 9, 2024 (KR) 10-2024-0061263

(51) Int. Cl. G03F 7/004; C07F 7/22; G03F 7/00; G03F 7/20

(52) U.S. Cl. CPC G03F 7/0042; C07F 7/2224; G03F 7/0048; G03F 7/2004; G03F 7/70033

(57) ABSTRACT

A pattern formation method may use a resist composition. The resist composition may include an organometallic compound represented by any one of Formulae 1-1 to 1-4, an additive represented by Formula 2, and a solvent. The solvent may include a non-polar solvent, a polar aprotic solvent, or a combination thereof.

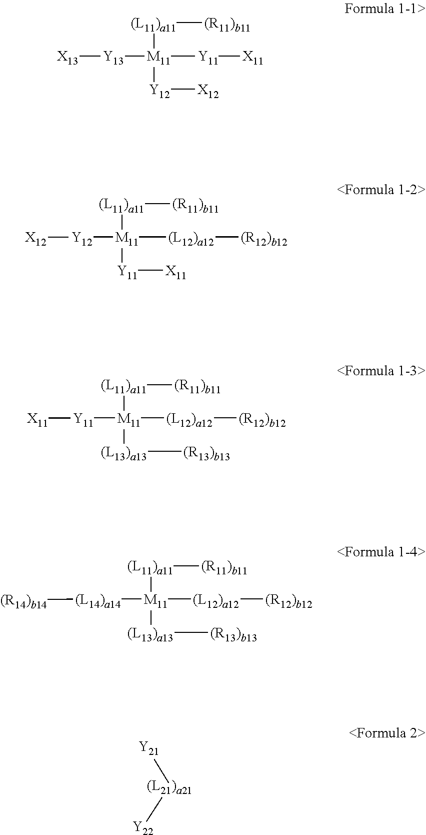

Refer to the specification for the descriptions of M₁₁, L₁₁ to L₁₄, a11 to a14, R₁₁ to R₁₄, b11 to b14, Y₁₁ to Y₁₃, X₁₁ to X₁₃, Y₂₁, Y₂₂, L₂₁, and a21 in Formulae 1-1 to 1-4 and 2.

### CROSS-REFERENCE TO RELATED APPLICATION

This application is based on and claims priority under 35 USC § 119 to Korean Patent Application No. 10-2024-0061263, filed on May 9, 2024 in the Korean Intellectual Property Office, the disclosure of which is incorporated by reference herein in its entirety.

### BACKGROUND

### 1. Field

The disclosure relates to a resist composition and a pattern formation method using the same.

### 2. Description of the Related Art

In semiconductor manufacturing, resists, of which physical properties change in response to light, are being used to form fine patterns. Among these resists, chemically amplified resists have been widely used. In the case of chemically amplified resists, an acid formed through a reaction between light and a photoacid generator reacts with a base resin again to change the solubility of the base resin with respect to a developer, thereby enabling patterning.

However, in the case of chemically amplified resists, the diffusion of the formed acid into non-exposed areas may lead to poor pattern uniformity and increased surface roughness. In addition, with increasingly miniaturized semiconductor processes, it is not easy to control the diffusion of acids, and thus there may be a need to develop a new type of resist.

Recently, in order to overcome the limits of chemically amplified resists, attempts have been made to develop materials of which physical properties change due to exposure to light. However, the dose required for exposure is still high.

### SUMMARY

Provided are a resist composition which has improved storage stability, whose properties change even with low doses of exposure, and which provides patterns of improved resolution, and a method of forming a pattern using the same.

Additional aspects will be set forth in part in the description which follows and, in part, will be apparent from the description, or may be learned by practice of the presented embodiments of the disclosure.

According to an embodiment, a resist composition may include an organometallic compound represented by any one of Formulae 1-1 to 1-4, an additive represented by Formula 2, and a solvent, wherein the solvent may include a non-polar solvent, a polar aprotic solvent, or a combination thereof.

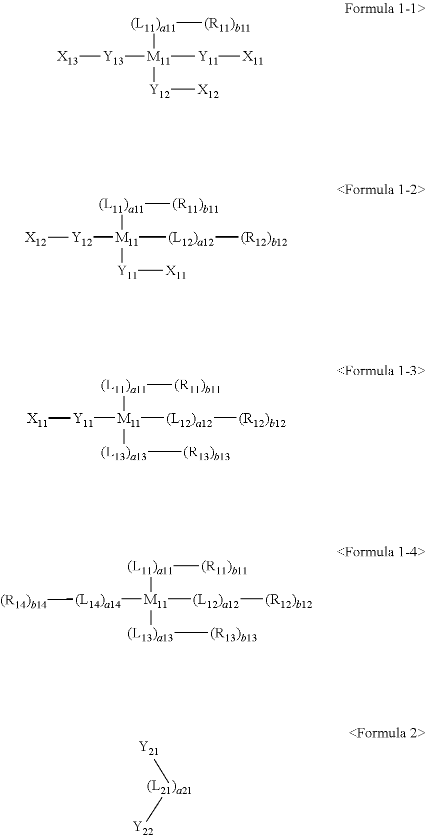

wherein in Formulae 1-1 to 1-4 and 2,
M₁₁ may be indium (In), tin (Sn), antimony (Sb), tellurium (Te), thallium (Tl), lead (Pb), bismuth (Bi), or polonium (Po);
L₁₁ to L₁₄ each independently may be a single bond or a linear, branched or cyclic C₁-C₃₀ divalent hydrocarbon group,
a11 to a14 each independently may be selected from integers of 1 to 4,
R₁₁ to R₁₄ are each independently a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
an adjacent two of R₁₁ to R₁₄ optionally may be bonded to each other to form a condensed ring,
b11 to b14 each independently may be selected from integers of 1 to 4,
Y₁₁ to Y₁₃ each independently may be O, O(C═O), S, S(C═O), NX₁₄ or N(C═O),
X₁₁ to X₁₄ each independently may be hydrogen, deuterium, or a linear, branched, or cyclic C₁-C₃₀ monovalent hydrocarbon group optionally including a heteroatom,
Y₂₁ and Y₂₂ each independently may be a linear, branched or cyclic C₁-C₃₀ monovalent hydrocarbon group including at least one selected from the group consisting of an oxygen atom, a sulfur atom, a nitrogen atom, and a phosphorus atom as a heteroatom,
L₂₁ may be a single bond, double bond, or a linear, branched, or cyclic C₁-C₃₀ divalent hydrocarbon group,
each a21 independently may be selected from integers of 1 to 4,
an adjacent two of Y₂₁, Y₂₂ and L₂₁ optionally may be bonded to each other to form a condensed ring.

According to an embodiment of the disclosure, a method of forming a pattern may include applying the resist composition to form a resist film, exposing at least a portion of the resist film to high energy rays to provide an exposed resist film, and developing the exposed resist film using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method of forming a pattern, according to an embodiment;

FIGS. 2A to 2C are side cross-sectional views showing a method of forming a pattern, according to an embodiment;

FIGS. 3A to 3E are cross-sectional side views showing a method of forming a patterning structure, according to an embodiment;

FIGS. 4A to 4E are side cross-sectional views showing a method of forming a semiconductor device, according to an embodiment;

FIG. 5A is a diagram showing the change in film thickness after development according to dose, in Example 1-1;

FIG. 5B is a diagram showing the change in film thickness after development, according to dose, in Comparative Example 1-1; and

FIGS. 6A to 6E are diagrams showing changes in film thickness after development, according to dose, in Examples 2-1 to 2-5, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As the disclosure allows for various changes and numerous embodiments, particular embodiments will be illustrated in the drawings and described in detail in the written description. However, this is not intended to limit the disclosure to particular modes of practice, and it is to be appreciated that all modifications, equivalents, and substitutes that do not depart from the spirit and technical scope of the disclosure are encompassed in the disclosure. In describing the disclosure, when it is determined that the specific description of the known related art unnecessarily obscures the gist of the disclosure, the detailed description thereof will be omitted.

Although the terms “first”, “second”, “third”, and the like may be used herein to describe various elements, these terms are only used to distinguish one element from another and the order, type, or the like of the elements are not limited thereby.

In this specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cₓ-C_{y}” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound including carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e. g., a phenyl group, a 1-naphthyl group, and a 2-naphthyl group); an arylalkyl group (e. g., a benzyl group and a diphenylmethyl group); a heteroatom-including monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or a combination thereof. Additionally, some of hydrogens in these groups may be substituted with a moiety including a heteroatom such as oxygen, sulfur, nitrogen, phosphorous or halogen atoms, or some of carbons in these groups may be replaced by a moiety including a heteroatom such as oxygen, sulfur, nitrogen or phosphorous, and thus these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic acid anhydride moieties, or the like.

The term “divalent hydrocarbon group” as used herein is a divalent residue and refers to a system in which any one hydrogen atom of the monovalent hydrocarbon group is replaced by a binding site with an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and examples thereof may include a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and examples thereof may include a methylene group, an ethylene group, a propylene group, a butylene group, and an isobutylene group.

The term “halogenated alkyl group” as used herein refers to a group in which at least one substituent of an alkyl group is substituted with a halogen atom, and examples thereof include CF₃. The halogen atom is F, Cl, Br or I.

The term “alkoxy group” as used herein refers to a monovalent group represented by formula —OA₁₀₁, wherein A₁₀₁ is an alkyl group. Specific examples thereof include a methoxy group, an ethoxy group, an isopropyloxy group, and the like.

The term “alkylthio group” as used herein refers to a monovalent group represented by formula —SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof include —OCF₃ and the like.

The term “halogenated alkylthio group” as used herein refers to a group in which one or more hydrogen atoms of an alkylthio group are substituted with a halogen atom, and specific examples thereof include —SCF₃ and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group represented by formula —OA₁₀₂, wherein A₁₀₂ is a cycloalkyl group. Specific examples thereof include a cyclopropoxy group, a cyclobutoxy group, and the like.

The term “cycloalkylthio group” as used herein refers to a monovalent group represented by formula —SA₁₀₂, where A₁₀₂ is a cycloalkyl group.

As used herein, the term “heterocycloalkyl group” refers to a cycloalkyl group in which some carbon atoms are substituted with a moiety including a heteroatom, such as oxygen, sulfur, or nitrogen, and the heterocycloalkyl group may include an ether bond, an ester bond, a sulfonate ester bond, a carbonate, a lactone ring, a sultone ring, or a carboxylic anhydride moiety. The term “heterocycloalkylene group” as used herein refers to a group in which some carbon atoms of the cycloalkylene group are substituted with a moiety including a heteroatom such as oxygen, sulfur, or nitrogen.

The term “heterocycloalkoxy group” as used herein refers to a monovalent group represented by formula —OA₁₀₃, wherein A₁₀₃ is a heterocycloalkyl group.

The term “heterocycloalkylthio group” as used herein refers to a monovalent group represented by formula —SA₁₀₃, wherein A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “cycloalkenyl group” as used herein refers to a monovalent unsaturated hydrocarbon cyclic group including at least one carbon-carbon double bond. The term “cycloalkenylene group” as used herein refers to a divalent unsaturated hydrocarbon cyclic group including at least one carbon-carbon double bond.

The term “heterocycloalkenyl group” as used herein refers to a cycloalkenyl group in which some carbon atoms are substituted with a moiety including a heteroatom, such as oxygen, sulfur, or nitrogen. The term “heterocycloalkenylene group” as used herein refers to a cycloalkenylene group in which some carbon atoms are substituted with a moiety including a heteroatom, such as oxygen, sulfur, or nitrogen.

The term “alkynyl group” as used herein refers to a linear or branched monovalent unsaturated aliphatic hydrocarbon group including one or more carbon-carbon triple bonds.

The term “aryl group” as used herein refers to a monovalent group including a carbocyclic aromatic system, and examples thereof include a phenyl group, a naphthyl group, an anthracenyl group, a phenanthrenyl group, a pyrenyl group, and a chrysenyl group. The term “arylene group” as used herein refers to a divalent group including a carbocyclic aromatic system.

The term “aryloxy group” as used herein refers to a monovalent group represented by formula —OA₁₀₄, where A₁₀₄ is an aryl group.

The term “arylthio group” as used herein refers to a monovalent group represented by formula —SA₁₀₄, where A₁₀₄ is an aryl group.

The term “heteroaryl group” as used herein refers to a monovalent group including a heterocyclic aromatic system, and examples thereof include a pyridinyl group, a pyrimidinyl group, and a pyrazinyl group. The term “heteroarylene group” as used herein refers to a divalent group including a heterocyclic aromatic system.

The term “heteroaryloxy group” as used herein refers to a monovalent group represented by formula —OA₁₀₅, where A₁₀₅ is a heteroaryl group.

The term “heteroarylthio group” as used herein refers to a monovalent group represented by formula —SA₁₀₅, where A₁₀₅ is a heteroaryl group.

The term “arylalkyl group” as used herein refers to a group in which an alkyl group is substituted with a monovalent group having a carbocyclic aromatic system, and specific examples include a benzyl group, a diphenylmethyl group, etc.

The term “heteroarylalkyl group” as used herein refers to a group in which an alkyl group is substituted with a monovalent group having a heterocyclic aromatic system.

The term “heterocyclic group” as used herein refers to a monocyclic or polycyclic group having 1 to 60 carbon atoms including at least one heteroatom, and is a group that includes a monovalent group, a divalent group, and a trivalent group.

The term “substituent” as used herein includes deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or a combination thereof; and a combination thereof.

Hereinafter, embodiments will be described in detail with reference to the accompanying drawings, wherein like reference numerals denote the same or substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Resist Composition]

Resist compositions according to embodiments may include an organometallic compound represented by any one of Formulae 1-1 to 1-4, an additive represented by Formula 2, and a solvent, wherein the solvent includes a non-polar solvent, a polar aprotic solvent, or a combination thereof:

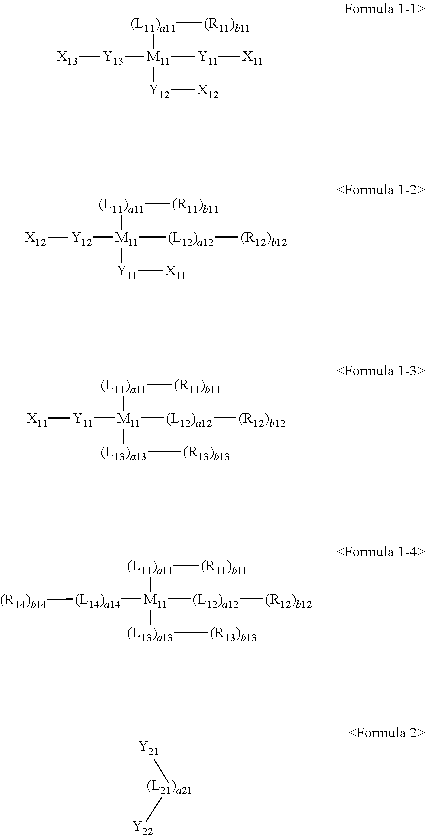

wherein in Formulae 1-1 to 1-4 and Formula 2,
M₁₁ may be indium (In), tin (Sn), antimony (Sb), tellurium (Te), thallium (Tl), lead (Pb), bismuth (Bi), or polonium (Po);
L₁₁ to L₁₄ each independently may be a single bond or a linear, branched or cyclic C₁-C₃₀ divalent hydrocarbon group,
a11 to a14 are each independently may be selected from integers of 1 to 4,
R₁₁ to R₁₄ each independently may be a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, substituted or unsubstituted C₃-C₃₀ heterocycloalkenyl group, substituted or unsubstituted C₂-C₃₀ alkynyl group, substituted or unsubstituted C₆-C₃₀ aryl group, substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
an adjacent two of R₁₁ to R₁₄ optionally may be bonded to each other to form a condensed ring,
b11 to b14 each independently may be selected from integers of 1 to 4,
Y₁₁ to Y₁₃ each independently may be O, O(C═O), S, S(C═O), NX₁₄ or N(C═O),
X₁₁ to X₁₄ each independently may be be hydrogen, deuterium, or a linear, branched or cyclic C₁-C₃₀ monovalent hydrocarbon group optionally including a heteroatom,
Y₂₁ and Y₂₂ each independently may be a linear, branched or cyclic C₁-C₃₀ monovalent hydrocarbon group optionally including at least one selected from the group consisting of an oxygen atom, a sulfur atom, a nitrogen atom and a phosphorus atom as a heteroatom,
L₂₁ may be a single bond, double bond, or a linear, branched or cyclic C₁-C₃₀ divalent hydrocarbon group,
each a21 independently may be selected from an integer of 1 to 4,
an adjacent two of Y₂₁, Y₂₂ and L₂₁ optionally may be bonded to each other to form a condensed ring.

Exposure to high-energy rays changes solubility of the resist composition in a developer. The resist composition may be a negative resist composition in which unexposed portions of the resist film are dissolved and removed to form a negative resist pattern, or may be a positive resist composition in which exposed portions of the resist film are dissolved and removed to form a positive resist pattern. The resist composition may be modified in various ways, such as negative or positive, depending on the exposure intensity and/or the type of developer. For example, the resist composition may be a positive resist composition.

In addition, the resist composition according to an embodiment may be for an alkaline developing process using an alkaline developer for developing treatment when forming a resist pattern, or for a solvent developing process using a developer including an organic solvent for the developing treatment (hereinafter, also referred to as an organic developer). For example, the resist composition may be intended for a solvent development process.

Since the resist composition is a non-chemically amplified type, it may substantially not include a photoacid generator.

Since the physical properties of the organometallic compound change upon exposure to light, the resist composition may not substantially include compounds with a molecular weight of about 1,000 or more other than the organometallic compound and the additive.

The organometallic compound and the additive may be prepared by any appropriate method, or commercially available products may be used.

The structure (composition) of the organometallic compound may be identified through Fourier transform infrared (FT-IR) analysis, NMR analysis, X-ray fluorescence (XRF) analysis, mass spectrometry, ultra violate (UV) analysis, single crystal X-ray structure analysis, powder X-ray diffraction (PXRD) analysis, liquid chromatography (LC), size exclusion chromatography (SEC) analysis, thermal analysis, etc. A detailed confirmation method is as described in Examples below.

### <Organometallic Compounds>

The molecular weight of the organometallic compound may be about 3000 g/mol or less. For example, the molecular weight of the organometallic compound may be 2000 g/mol or less.

Although not limited to a specific theory, radicals may be formed in the organometallic compound by heat and/or high energy rays. For example, organometallic compounds may be decomposed by high-energy rays, and in particular, a radical may be formed from the M₁₁-carbon bond of the organometallic compound. Accordingly, the physical properties of the organometallic compound, particularly its solubility in the developer, may change.

The organometallic compound represented by any one of Chemical Formulae 1-1 to 1-4 must include at least one of R11 to R14, which have relatively low C—H bond dissociation energies, therefore, the photosensitivity to high-energy radiation, especially EUV, may be improved.

For example, in Formulae 1-1 to 1-4, M₁₁ may be In, Sn, or Sb. For example, in Formulae 1-1 to 1-4, M₁₁ may be Sn.

For example, in Formulae 1-1 to 1-4, L₁₁ to L₁₄ may each independently be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, substituted or unsubstituted C₂-C₃₀ alkenylene group, substituted or unsubstituted C₃-C₃₀ cycloalkenylene group, substituted or unsubstituted C₃-C₃₀ heterocycloalkenylene group, substituted or unsubstituted C₆-C₃₀ arylene group, or a substituted or unsubstituted C₁-C₃₀ heteroarylene group.

For example, in Formulae 1-1 to 1-4, L₁₁ to L₁₄ may each independently be selected from a single bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

For example, in Formulae 1-1 to 1-4, L₁₁ to L₁₄ may each independently be selected from a single bond; and a C₁-C₃₀ alkylene group substituted or unsubstituted with deuterium, a halogen, a hydroxyl group, a cyano group, a C₁-C₂₀ alkyl group, a C₁-C₂₀ halogenated alkyl group, or a combination thereof.

For example, in Formulae 1-1 to 1-4, a11 to a14 may each independently be an integer of 1 or 2.

For example, in Formulae 1-1 to 1-4, R₁₁ to R₁₄ may each independently be selected from a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, C₁-C₃₀ heteroaryl group and C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

For example, in Formulas 1-1 to 1-4, R₁₁ to R₁₄ may each independently be a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

For example, in Formulae 1-1 to 1-4, R₁₁ to R₁₄ may each independently be selected from any of the following Formulae 3-1 to 3-20:

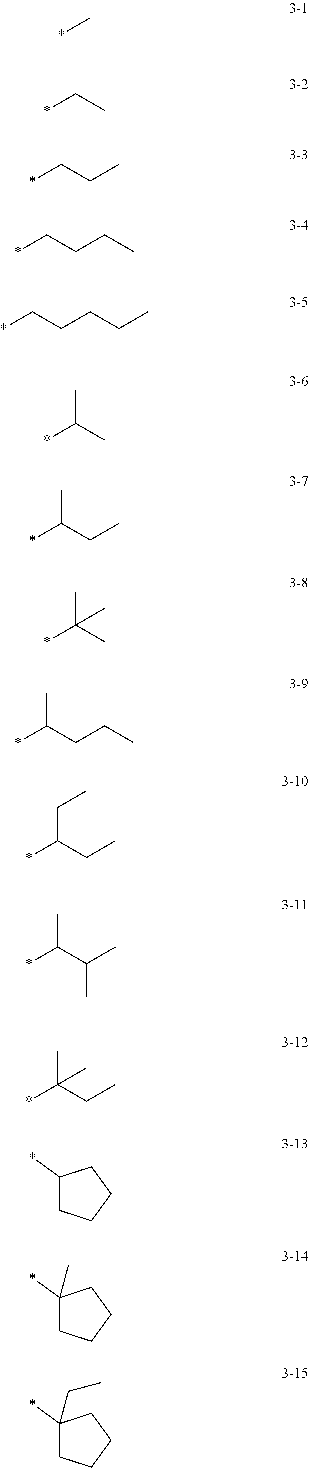

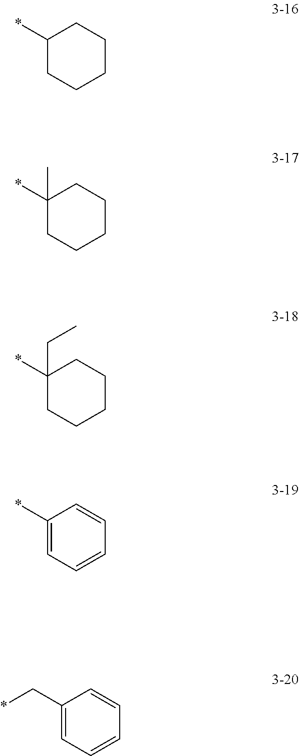

wherein, in Formulae 3-1 to 3-20,
at least one hydrogen optionally may be substituted with deuterium, a halogen atom, a cyano group, a nitro group, a hydroxyl group, a thiol group, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, or a combination thereof.

In Formulae 1-1 to 1-4, b11 to b14 each refer to the number of substitutions for R₁₁ to R₁₄, for example, in Formulae 1-1 to 1-4, b11 to b14 may each independently be 1 or 2.

An adjacent two of R₁₁ to R₁₄ optionally may be bonded to each other to form a condensed ring.

For example, an adjacent two of the plurality of R₁₁ optionally may be bonded to each other to form a condensed ring, an adjacent two of the plurality of R₁₂ optionally may be bonded to each other to form a condensed ring, an adjacent two of the plurality of R₁₃ optionally may be bonded to each other to form a condensed ring, and an adjacent two of the plurality of R₁₄ optionally may be bonded to each other to form a condensed ring.

As for another example, an adjacent two of R₁₁ to R₁₄ optionally may be bonded to each other to form a condensed ring.

For example, in Formulae 1-1 to 1-4, Y₁₁ to Y₁₃ may each independently be O, O(C═O), S, or S(C═O).

For example, in Formulas 1-1 to 1-4, X₁₁ to X₁₄ may each independently be selected from hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

For example, in Formulae 1-1 to 1-4, X₁₁ to X₁₄ may each independently be selected from hydrogen; deuterium; and a C₁-C₃₀ alkyl group, a C₁-C₃₀ halogenated alkyl group, a C₃-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group and a C₂-C₃₀ heteroarylalkyl group, each unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or a combination thereof.

For example, in Formulae 1-1 to 1-4, X₁₁ to X₁₄ may each independently be selected from hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, and a C₆-C₃₀ aryl group, each unsubstituted or substituted with deuterium, a halogen, or a combination thereof.

In particular, in Formulae 1-1 to 1-4, X₁₁ to X₁₄ may each independently be selected from hydrogen; deuterium; and a methyl group, an ethyl group, a n-propyl group, an iso-propyl group, a n-butyl group, a sec-butyl group, an iso-butyl group, a tert-butyl group, a cyclopentyl group, a cyclohexyl group, an ethenyl group, a cyclopentenyl group, a cyclopentadienyl group, a cyclohexenyl group, a cyclohexadienyl group, an ethynyl group, a phenyl group and a naphthyl group, each unsubstituted or substituted with deuterium, a halogen, a methyl group, an ethyl group, a phenyl group, a naphthyl group or a combination thereof.

In an embodiment, the organometallic compound represented by any one of Formulae 1-1 to 1-4 may be selected from Group I below:

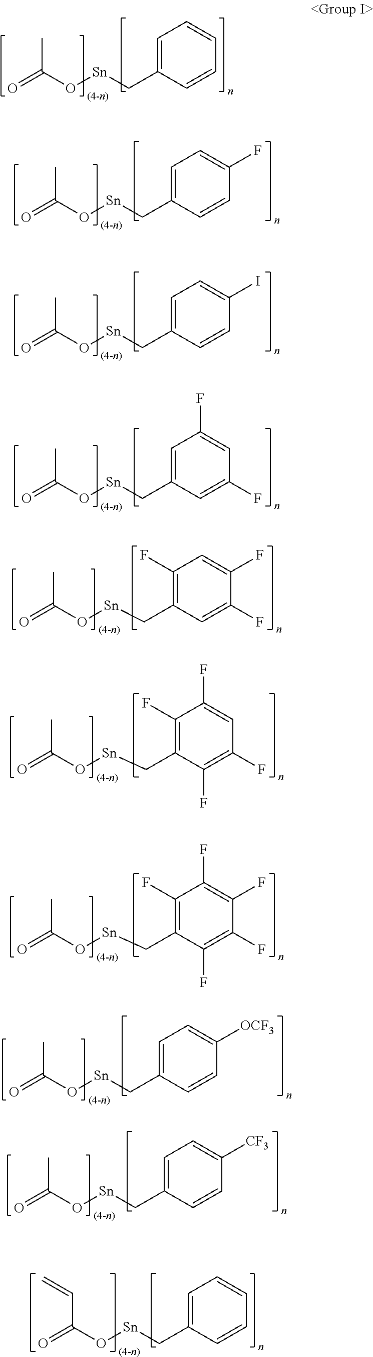

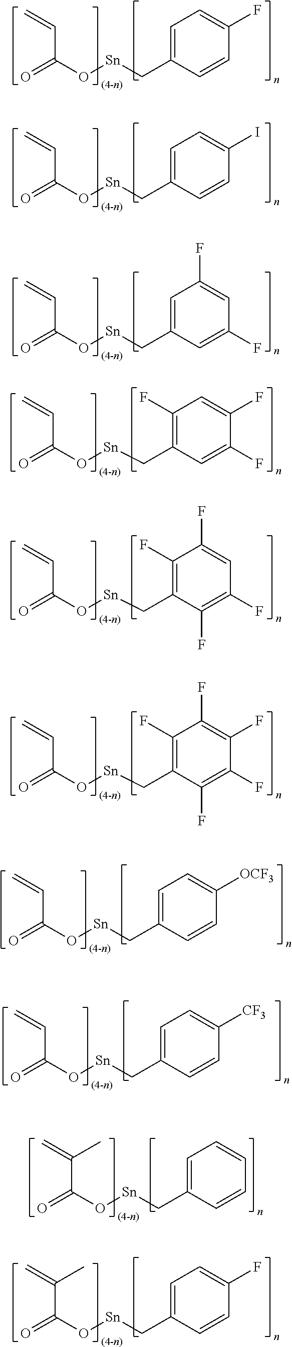

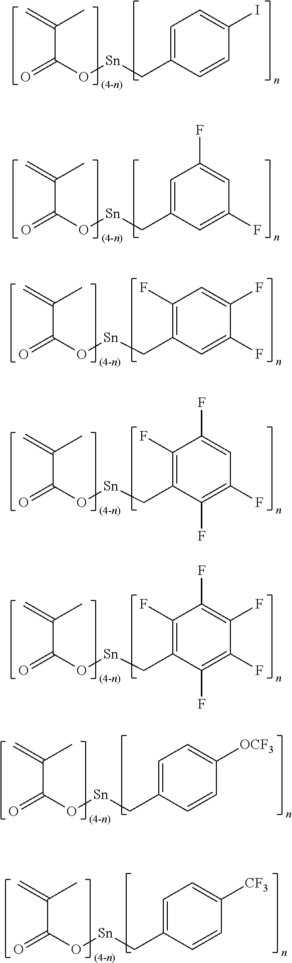

wherein in Group I, n may be an integer from 1 to 4.

The organometallic compound may be any one represented by any one of Formulae 1-1 to 1-4, or a mixture of two or more may be used.

In the resist composition, the organometallic compound may be about 0.01 parts by weight to about 100 parts by weight, for example, 0.2 or more, 0.5 or more, 1 or more, 1.5 or more, 90 or less, or 80 or less parts by weight, based on 100 parts by weight of the resist composition. If the above-mentioned range is satisfied, chemical bonds between organometallic compounds are sufficiently formed and side reactions are suppressed, thereby providing a resist composition with improved sensitivity and/or resolution.

### <Additives>

For example, in Group I, n may be 2.

For example, in Formula 2, Y₂₁ may be represented by any one of Formulae 4-1 to 4-5, and Y₂₂ may be represented by any one of Formulae 4-6 to 4-10:

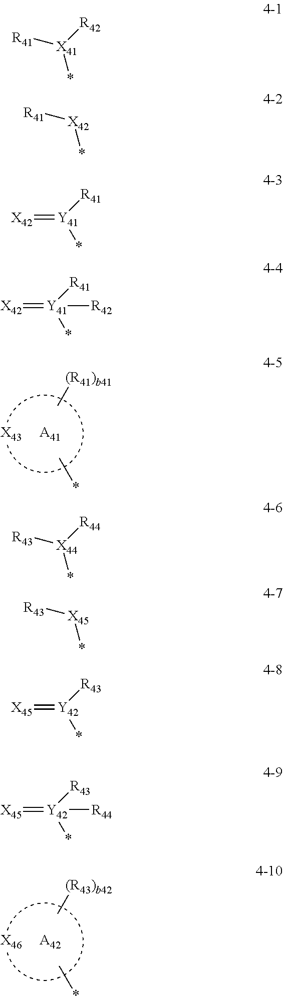

wherein in Formulae 4-1 to 4-10,
X₄₁ and X₄₄ are each independently N or P,
X₄₂ and X₄₅ are each independently O or S,
X₄₃ and X₄₆ are each independently O, S, N or P,
Y₄₁ and Y₄₂ are each independently C, S or P,
A₄₁ is a C₁-C₃₀ heterocyclic group containing X₄₃ as a ring member,
A₄₂ is a C₁-C₃₀ heterocyclic group containing X₄₆ as a ring member,
R₄₁ to R₄₄ are each independently hydrogen, deuterium, a halogen, a cyano group, a nitro group, a hydroxyl group, a thiol group, an amino group, a carboxylate group, or a linear, branched or cyclic C₁-C₃₀ divalent hydrocarbon group,
b41 and b42 are each independently selected from integers from 1 to 10, and
* is a bonding site with a neighboring atom.

In an embodiment, the additive may include a structure where any one selected from X₄₁ to X₄₃ and any one selected from X₄₄ to X₄₆ coordinate with any metal atom, for example, M₁₁, to form a 5-membered, 6-membered, or 7-membered ring.

For example, in Formulae 4-5 and 4-10, A₄₁ and A₄₂ are each independently: i) a monovalent group derived from a first ring, ii) a monovalent group derived from a condensed ring where two or more first rings are condensed with each other, or iii) a monovalent group derived from a condensed ring where one or more first rings and one or more second rings are condensed with each other;
the first ring may be tetrahydropyran, dihydropyran, pyrane, tetrahydrothiopyrane, dihydrothiopyrane, thiopyrane, tetrahydrofurane, dihydrofurane, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine or triazine, and
the second ring may be cyclopentane, cyclopentadiene, cyclohexane, cyclohexene, cyclohexadiene, benzene, or naphthalene.

For example, in Formulae 4-5 and 4-10, A₄₁ and A₄₂ may be each independently: i) a monovalent group derived from a first ring, ii) a monovalent group derived from a condensed ring where two or more first rings are condensed with each other, or iii) a monovalent group derived from a condensed ring where one or more first rings and one or more second rings are condensed with each other;
the first ring may be tetrahydropyran, dihydropyran, pyran, tetrahydrothiopyran, dihydrothiopyran, thiopyran, tetrahydrofuran, dihydrofuran, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine or triazine; and
the second ring may be benzene.

For example, in Formulae 4-1 to 4-10, R₄₁ to R₄₄ may each independently be selected from hydrogen; deuterium; a halogen; a cyano group; a nitro group; a hydroxyl group; a thiol group; an amino group; a carboxylate group; and a C₁-C₃₀ alkyl group, a C₁-C₃₀ halogenated alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

For example, in Formulae 4-1 to 4-10, R₄₁ to R₄₄ may each independently be selected from hydrogen; deuterium; a halogen; a cyano group; a nitro group; a hydroxyl group; a thiol group; an amino group; a carboxylate group; and a C₁-C₃₀ alkyl group, a C₁-C₃₀ halogenated alkyl group, a C₃-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or a combination thereof.

In an embodiment, in Formula 2, i) Y₂₁ may be represented by Formula 4-5, and Y₂₂ may be represented by any of Formulae 4-6 to 4-10, or

ii) Y₂₁ may be represented by any one of Formulae 4-1 to 4-5, and Y₂₂ may be represented by Formula 4-10.

In another embodiment, in Formula 2, Y₂₁ may be represented by Formula 4-5, and Y₂₂ may be represented by Formula 4-10.

For example, in Formula 2, L₂₁ may be a single bond, a double bond, a substituted or unsubstituted C₁-C₃₀ alkylene group, a substituted or unsubstituted C₃-C₃₀ cycloalkylene group, or a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

For example, in Formula 2, L₂₁ may be selected from a single bond; double bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

For example, in Formula 2, L₂₁ may be selected from a single bond; a double bond; and a C₁-C₃₀ alkylene group and a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or a combination thereof.

In an embodiment, the additive may be represented by Formula 2-1:

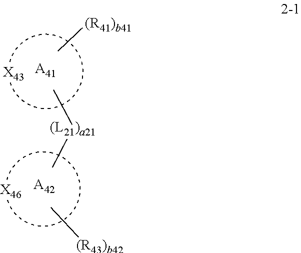

wherein in Formula 2-1,

The descriptions for X₄₃, X₄₆, A₄₁, A₄₂, L₂₁, a21, R₄₁ to R₄₄, b41, and b42 refer to the aforementioned details.

In an embodiment, the additive may be represented by the following Formula 2-11 or 2-12:

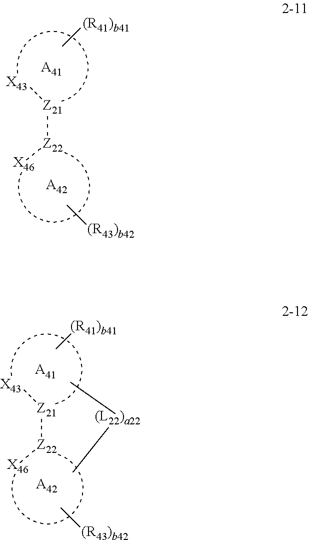

wherein in Formulae 2-11 and 2-12,
X₄₃ and X₄₆ each independently may be O, S, N or P,
A₄₁ may be a C₁-C₃₀ heterocyclic group containing X₄₃ as a ring member,
A₄₂ is a C₁-C₃₀ heterocyclic group containing X₄₆ as a ring member,
Z₂₁ and Z₂₂ each independently may be C or N,
The bond between Z₂₁ and Z₂₂ may be a single bond or a double bond,
L₂₂ may be selected from a single bond; a double bond; and a C₁-C₃₀ alkylene group and a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or a combination thereof,
a22 may be selected from integers 1 to 4,
R₄₁ to R₄₄ each independently may be a linear, branched or cyclic C₁-C₃₀ divalent hydrocarbon group, and
b41 and b42 each independently may be selected from integers from 1 to 10.

In Formulae 2-11 and 2-12, the bond between X₄₃ and Z₂₁ and the bond between Z₂₂ and X₄₆ may each independently be a single bond or a double bond.

For example, in Formulae 2-11 and 2-12, there may be three chemical bonds between X₄₃ and X₄₆, and these three chemical bonds include the chemical bond between X₄₃ and Z₂₁, the chemical bond between Z₂₁ and Z₂₂, and the chemical bond between Z₂₂ and X₄₆.

In an embodiment, the additive may be represented by any one of Formulae 2-21 to 2-26 below:

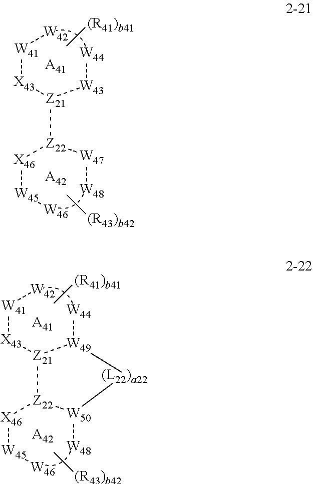

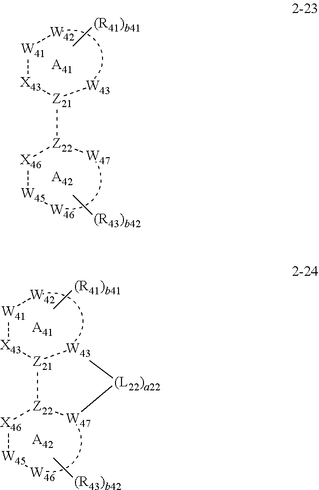

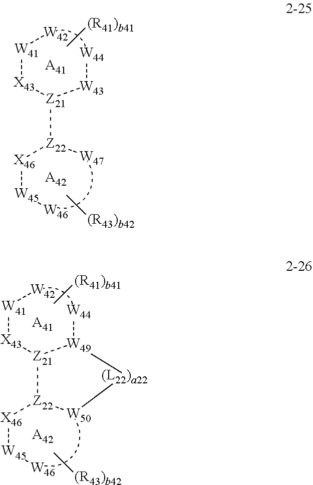

wherein, in Formulae 2-21 to 2-26,
X₄₃ and X₄₆ are each independently O, S, N or P,
A₄₁ is a C₁-C₃₀ heterocyclic group containing, as ring members, Z₂₁, X₄₃, W₄₁ to W₄₄ and W₄₉,
A₄₂ is a C₁-C₃₀ heterocyclic group containing, as ring members, Z₂₂, X₄₆, W₄₅ to W₄₈ and W₅₀,
Z₂₁ and Z₂₂ are each independently C or N,
W₄₁ to W₅₀ are each independently C(R₄₁ₐ), C(R₄₁ₐ)(R_{41b}), C(R₄₃ₐ), C(R₄₃ₐ)(R_{43b}), or N,
The bonds between Z₂₁ and Z₂₂, beween Z₂₁ and X₄₃, between X₄₃ and W₄₁, between W₄₁ and W₄₂, between Z₂₁ and W₄₃, between W₄₃ and W₄₄, between Z₂₂ and W₄₆, between W₄₆ and W₄₅, between W₄₅ and W₄₆, between Z₂₂ and W₄₇, between W₄₇ and W₄₈, between W₄₄ and W₄₉, between W₄₉ and Z₂₁, between Z₂₂ and W₅₀, between W₄₈ and W₅₀, between W₄₂ and W₄₃, between W₄₆ and W₄₇, between W₄₂ and W₄₉, and between W₄₆ and W₅₀ are each either a single bond or a double bond;
L₂₂ is selected from a single bond; a double bond; and a C₁-C₃₀ alkylene group and a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or a combination thereof,
a22 is selected from integers of 1 to 4,
R₄₁, R₄₃, R₄₁ₐ, R_{41b}, R₄₃ₐ and R_{43b} are each independently a linear, branched or cyclic C₁-C₃₀ divalent hydrocarbon group, and
b41 and b42 are each independently selected from integers from 1 to 10.

In an embodiment, the additive may be represented by any one of Formulae 2-31 to 2-48 below:

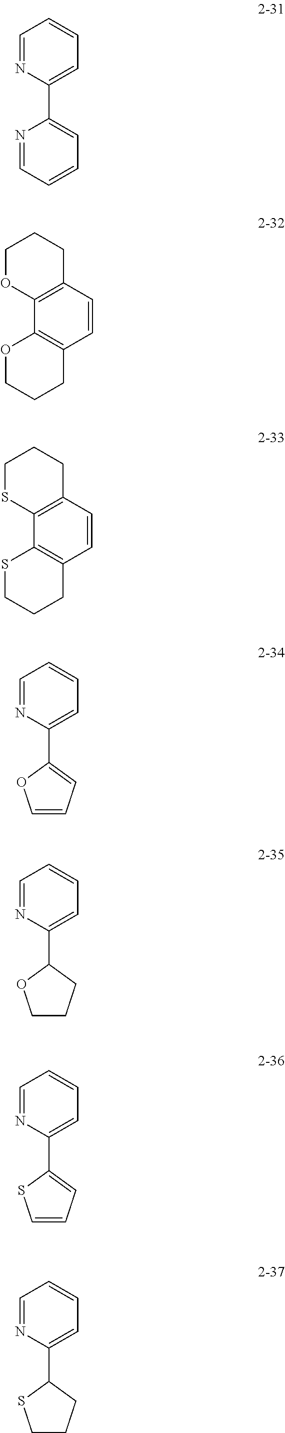

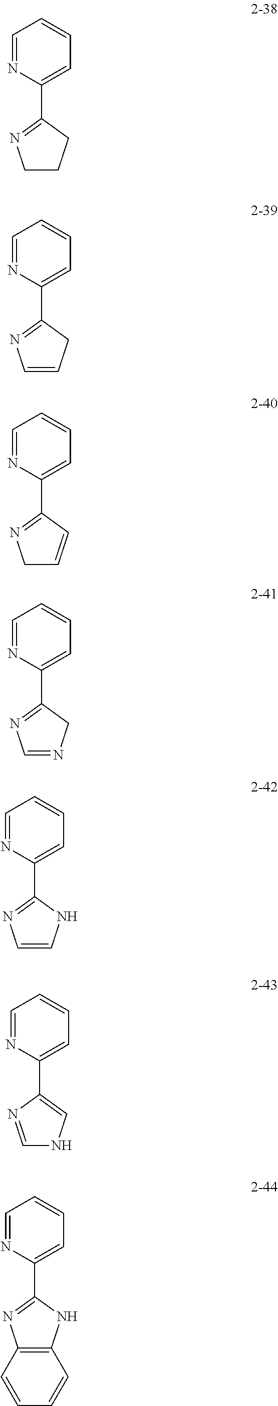

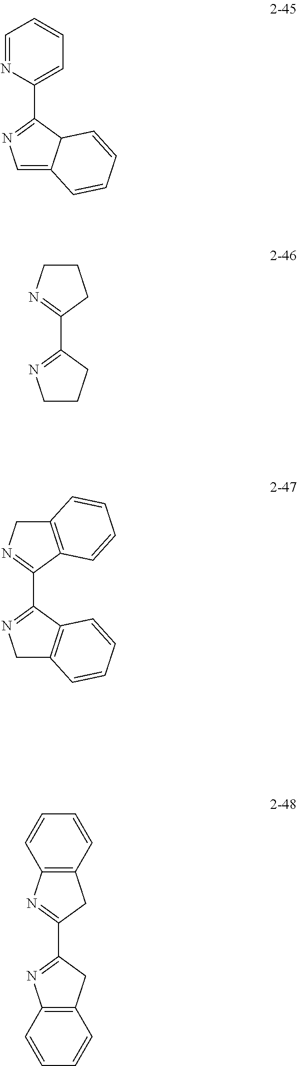 [SMILES: C1=CC2=CN=C(c3ccccn3)C2C=C1 ; C1CN=C(C2=NCCC2)C1 ; c1ccc2c(c1)CN=C2C1=NCc2ccccc21 ; c1ccc2c(c1)CC(C1=Nc3ccccc3C1)=N2]

wherein in Formulae 2-31 to 2-48,
at least one hydrogen optionally may be substituted with deuterium, a halogen, a cyano group, a nitro group, a hydroxyl group, a thiol group, a C₁-C₂₀ alkyl group, a C₁-C₂₀ halogenated alkyl group, a C₃-C₂₀ cycloalkyl group, a C₂-C₂₀ alkenyl group, a C₃-C₂₀ cycloalkenyl group, a C₃-C₂₀ heterocycloalkenyl group, a C₂-C₂₀ alkynyl group, a C₆-C₂₀ aryl group, a C₇-C₂₀ arylalkyl group, a C₁-C₂₀ heteroaryl group, a C₂-C₂₀ heteroarylalkyl group, or a combination thereof, and
at least one carbon and nitrogen may optionally combine with neighboring carbon or nitrogen to form a ring.

In an embodiment, the additive may be selected from Group II below:

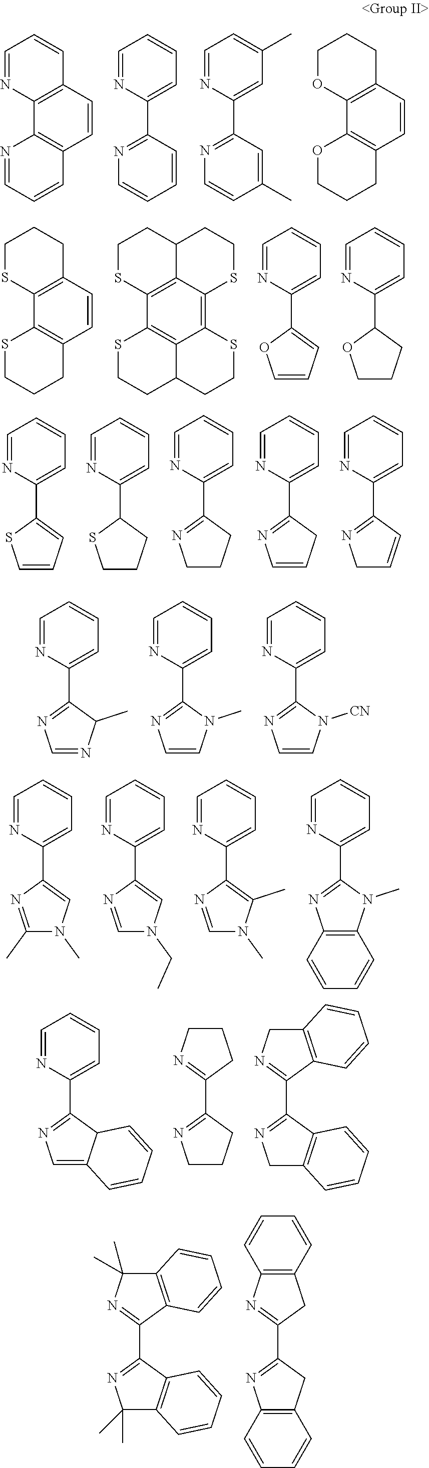

The additive may includes N, O, S, and/or P, which provide lone-pair electrons, enabling coordination bonding with the organometallic compound, thereby enhancing the chemical stability of the organometallic compound.

Accordingly, the resist composition containing the additive may significantly reduce the hydrolysis and/or condensation reaction of the organometallic compound, and by controlling the characteristics, such as the polarity, of the solvent and/or developer used, the resist composition may be a positive resist composition.

The additive may be any one represented by Formula 2, or a mixture of two or more may be used.

In the resist composition, the additive may be about 0.01 parts by weight to about 100 parts by weight, for example, 0.2 or more, 0.5 or more, 1 or more, 1.5 or more, 90 or less, or 80 or less parts by weight, based on 100 parts by weight of the resist composition. If the above-mentioned range is satisfied, chemical bonds between organometallic compounds are sufficiently formed and side reactions are suppressed, thereby providing a resist composition with improved sensitivity and/or resolution.

In the resist composition, the additive may be included in an amount of about 0.1 parts by weight to about 100,000 parts by weight based on 100 parts by weight of the organometallic compound. For example, the additive may be included in an amount of about 10 parts by weight to about 1,000 parts by weight based on 100 parts by weight of the organometallic compound. If the above-mentioned range is satisfied, the resist composition may significantly improve storage stability while maintaining the photosensitivity at the level of a resist composition without the additive.

### <Solvent>

The solvent may be used alone or in combination with two or more different types.

The solvent may include non-polar solvents, polar aprotic solvents, or a combination thereof.

For example, the solvent may be polar aprotic solvents.

Non-polar solvents may include ether-based solvents, hydrocarbon-based solvents, and a combination thereof.

Polar aprotic solvents may include ether-based solvents, ketone-based solvents, amide-based solvents, ester-based solvents, sulfoxide-based solvents, and a combination thereof.

Examples of ether-based solvents include dialkyl ether solvents such as diethyl ether, dipropyl ether, dibutyl ether, diethylene glycol dimethyl ether, and dipropylene glycol dimethyl ether; cyclic ether solvents such as 1,4-dioxane, tetrahydrofuran and tetrahydropyran; and aromatic ring-containing ether solvents such as diphenyl ether and anisole.

Examples of ketone-based solvents include linear ketone solvents such as acetone, methyl ethyl ketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexyl ketone, diisobutyl ketone, and trimethylnonanone; cyclic ketone solvents such as cyclopentanone, cyclohexanone, cycloheptanone, cyclooctanone, and methylcyclohexanone; and other ketone solvents such as 2,4-pentanedione, acetonylacetone, and acetophenone.

Examples of amide-based solvents include cyclic amide solvents such as N,N′-dimethylimidazolidinone and N-methyl-2-pyrrolidone; and linear amide solvents such as N-methylformamide, N,N-dimethylformamide, N,N-diethylformamide, acetamide, N-methylacetamide, N,N-dimethylacetamide, and N-methylpropionamide.

Examples of ester-based solvents include acetate ester solvents such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; polyhydric alcohol-containing ether carboxylate solvents such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; lactone solvents such as γ-butyrolactone and δ-valerolactone; carbonate solvents such as dimethyl carbonate, diethyl carbonate, ethylene carbonate, and propylene carbonate; and other solvents such as ethylene glycol diacetate, methoxytriglycol acetate, ethyl propionate, n-butyl propionate, isoamyl propionate, diethyl oxalate, di-n-butyl oxalate, methyl acetoacetate, ethyl acetoacetate, diethyl malonate, dimethyl phthalate, and diethyl phthalate.

Examples of sulfoxide-based solvents include dimethyl sulfoxide and diethyl sulfoxide.

Examples of hydrocarbon-based solvents include aliphatic hydrocarbon solvents such as n-pentane, isopentane, n-hexane, isohexane, n-heptane, isoheptane, 2,2,4-trimethyl pentane, n-octane, isooctane, cyclohexane, and methylcyclohexane; and aromatic hydrocarbon solvents such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

For example, the solvent may be selected from ketone-based solvents, ester-based solvents, and a combination thereof.

For example, the solvent may be selected from linear ketone-based solvents, cyclic ketone-based solvents, polyhydric alcohol-containing ethercarboxylate-based solvents, lactone-based solvents, acetate ester-based solvents, and a combination thereof.

In particular, the solvent may be selected from methyl ethyl ketone, cyclopentanone, cyclohexanone, cycloheptanone, propylene glycol monomethyl ether acetate, γ-butyrolactone, δ-valerolactone, n-butyl acetate, and a combination thereof.

The resist composition may be substantially free of water, and therefore, the solvent may also be free of water. For example, the resist composition may contain 3 wt % or less of water, and the solvent may contain 3 wt % or less of water.

The solvent may be used in an amount of about 0 parts by weight to about 99.9 parts by weight based on 100 parts by weight of the resist composition. The solvent may be used alone, or in combination with two or more different types.

### <Optional Component>

The resist composition may further include, as needed, a surfactant, a crosslinking agent, a leveling agent, a colorant, or a combination thereof.

The resist composition may further include a surfactant to improve properties such as coating and development. Specific examples of surfactants include non-ionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. The surfactant may be either commercially available or synthetically produced. Examples of commercially available surfactants include KP341 (product of Shin-Etsu Chemical Co., Ltd.), Polyflow No.75 and Polyflow No.95 (products of Kyoeisha Chemical Co., Ltd.), F-Top EF301, F-Top EF303, and F-Top EF352 (products of Mitsubishi Materials Electronic Chemicals Co., Ltd.), MEGAFACE® F171, MEGAFACE® F173, R40, R41, R43 (products of DIC Corporation), Fluorad® FC430 and Fluorad® FC431 (products of 3M), AsahiGuard AG710 (product of AGC Inc.), and Surflon® S-382, Surflon SC-101, Surflon SC-102, Surflon SC-103, Surflon SC-104, Surflon SC-105, and Surflon SC-106 (products of AGC Seimi Chemical Co., Ltd.).

The surfactant may be included in an amount of about 0 parts by weight to about 20 parts by weight based on 100 parts by weight of the resist composition. The surfactant may be used alone, or in combination with two or more different types.

The method for preparing the resist composition is not particularly limited and may include, for example, mixing the polymer and any optional components in an organic solvent. The temperature and duration of mixing is not particularly limited. If necessary, filtration may be performed after mixing.

### [Pattern Formation Method]

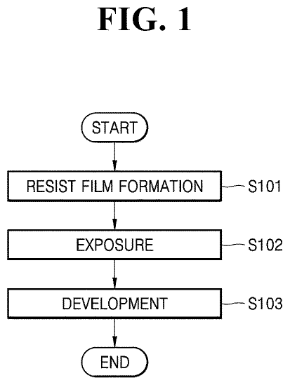

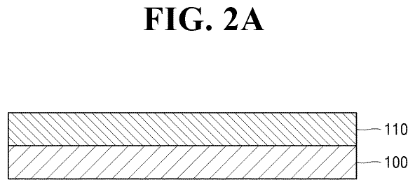

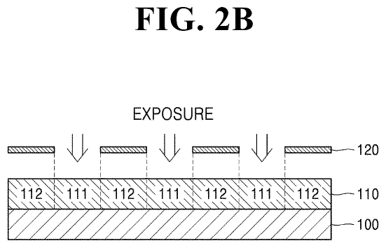

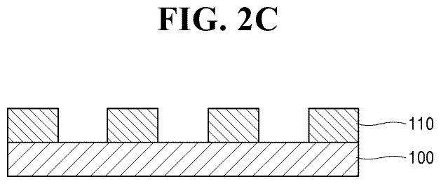

Hereinafter, the pattern forming method according to example embodiments will be described in more detail with reference to FIGS. 1 and 2A to 2C. FIG. 1 is a flowchart showing a pattern forming method according to example embodiments, and FIGS. 2A to 2C are side cross-sectional views showing the pattern forming method according to example embodiments. Hereinafter, a method of forming a pattern using a negative resist composition will be described as an example, but is not limited thereto.

Referring to FIG. 1, the pattern forming method includes applying a resist composition to form a resist film (S101), exposing at least a portion of the resist film to high-energy rays (S102), and developing the exposed resist film using a developer (S103). The above operations may be omitted if necessary, and they may be performed in a different order.

First, a substrate 100 is prepared. The substrate 100 may be, for example, a semiconductor substrate such as a silicon substrate or a germanium substrate, glass, quartz, ceramic, or copper. In some embodiments, the substrate 100 may include Ill-V group compounds such as GaP, GaAs or GaSb.

The resist composition may be applied to the substrate 100 to form a resist film 110 with the desired thickness, for example, by a coating method. If necessary, the resist film 110 may be heated (pre-baked, PB) to remove any remaining organic solvent. Alternatively, by heating the resist film 110, radicals may be generated, and subsequent exposure may cause these radicals to chemically bond, forming crosslinks.

The coating method may use spin coating, dipping, roller coating or other common coating methods. Among these, spin coating may be particularly used, and by adjusting the viscosity, concentration, and/or spin speed of the resist composition, a resist film 110 of the desired thickness may be formed. For example, the thickness of the resist film 110 may be about 10 nm to about 300 nm. For example, the thickness of the resist film 110 may be about 30 nm to about 200 nm.

The lower limit of the prebake temperature may be 60° C. or higher, for example, 80° C. or higher. Additionally, the upper limit of the prebake temperature may be 150° C. or lower, for example, 140° C. or lower. The lower limit of the prebake time may be 5 seconds or more, for example, 10 seconds or more. The upper limit of the prebake time may be 600 seconds or less, for example, 300 seconds or less.

Before applying the resist composition to the substrate 100, a sacrificial layer (not shown) for etching purposes may also be formed on the substrate 100. The sacrificial layer may refer to a layer where an image is transferred from the resist pattern, thereby transforming into a desired pattern. In an embodiment, the sacrificial layer may be formed to include insulating materials such as silicon oxide, silicon nitride, or silicon oxynitride. In some embodiments, the sacrificial layer may be formed to include conductive materials such as metals, metal nitrides, metal silicides, or metal silicide nitride films. In some embodiments, the sacrificial layer may be formed to include a semiconductor material such as polysilicon.

In an embodiment, an anti-reflection film may be further formed on the substrate 100 to increase or maximize the efficiency of the resist. The anti-reflection film may be an organic or inorganic anti-reflection film.

In an embodiment, a protective film may be further provided on the resist film 100 to reduce the influence of alkaline impurities included during the process. Additionally, when immersion exposure is performed, for example, a protective film for immersion may also be provided on the resist film 100 to avoid direct contact between an immersion medium and the resist film 110.

Next, at least a portion of the resist film 110 may be exposed to high energy rays. For example, high energy rays passing through a mask 120 may be irradiated onto at least a portion of the resist film 110. For this reason, the resist film 110 may have an exposed portion 111 and an unexposed portion 112.

Although not limited to a specific theory, radicals are generated in the exposed portion 111 by exposure, and chemical bonds are formed between the radicals, which may change the physical properties of the resist composition.

In some cases, the exposure may be performed by irradiating high energy rays through a mask with a certain pattern using a liquid such as water as a medium. Examples of the high-energy rays may include electromagnetic waves such as ultraviolet rays, deep ultraviolet rays, extreme ultraviolet (EUV) rays (wavelength of 13.5 nm), X-rays, and γ-rays; and charged particle beams such as electron beams (EBs) and a particle beams. Irradiation of these high-energy rays can be collectively referred to as “exposure.”

Various light sources may be used for the exposure, for example, a light source emitting laser beams in the UV range, such as a KrF excimer laser (wavelength of 248 nm), an ArF excimer laser (wavelength of 193 nm), and an F2 excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting EBs or EUVs may be used. During exposure, the exposure may be usually performed through a mask corresponding to a desired pattern, but when exposure light is an EB, the exposure may be performed through direct writing without using a mask.

The integrated dose of high-energy rays, for example, when using extreme ultraviolet rays as high-energy rays, may be 2000 mJ/cm² or less, for example 500 mJ/cm² or less. In addition, when EBs are used as the high energy rays, the integral dose may be 5,000 μC/cm² or less, or 1,000 μC/cm² or less.

In addition, when EBs are used as the high energy rays, the integral dose may be 5,000 μC/cm² or less, or 1,000 μC/cm² or less. The lower limit of the temperature of PEB may be 50° C. or more, for example 80° C. or more. The upper limit of the PEB temperature may be 250° C. or lower, for example 200° C. or lower. The lower limit of the time of the PEB time may be 5 seconds or more, for example 10 seconds or more. The upper limit of the time of the PEB may be 600 seconds or less, for example 300 seconds or less.

Next, the exposed resist film 110 may be developed using a developer. The exposed region 111 may be removed by being washed away by the developer, and the unexposed portion 112 may remain without being washed away by the developer.

Examples of the developer include a developer including an organic solvent (hereinafter also referred to as “organic developer”). Examples of a developing method are a dipping method, a puddle method, a spray method, a dynamic injection method, and the like. A developing temperature may be, for example, about 5° C. or more and about 60° C. or less, and a developing time may be, for example, about 5 seconds or more and about 300 seconds or less.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of an amount of the alkaline compound included in the alkaline developer may be 0.1 wt % or more or 0.5 wt % or more, or 1 wt % or more. Additionally, an upper limit of the amount of the alkaline compound included in the alkaline developer may be 20 wt % or less, or 10 wt % or less, or 5 wt % or less.

Examples of the organic solvent included in the organic developer may include the same organic solvents as those described in the part of <Solvent> of [Resist composition]. Alternatively, as an organic solvent, alcohol-based solvents or lactate-based solvents may be used.

Examples of alcohol-based solvents include monoalcohol solvents such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and polyhydric alcohol-including ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of lactate-based solvents include methyl lactate, ethyl lactate, n-butyl lactate, and n-amyl lactate.

For example, nBA (n-butyl acetate), PGME, PGMEA, ethyl lactate, GBL (γ-butyrolactone), and IPA (isopropanol) may be used as the organic developer. The organic developer may further include organic acids such as acetic acid, formic acid, and citric acid.

The lower limit of the organic solvent content in the organic developer may be 80 wt % or more, for example 90 wt % or more, 95 wt % or more, or 99 wt % or more.

Organic developers may also include surfactants. Additionally, organic developers may include trace amounts of moisture. Additionally, during development, it is possible to stop the development process by replacing the organic developer with a different type of solvent.

The resist pattern after development may be further cleaned. Cleaning solutions such as ultrapure water and rinse solution may be used. There are no particular restrictions on the rinse solution as long as it does not dissolve the resist pattern, and common solutions containing organic solvents may be used. For example, the rinse liquid may be an alcohol-based solvent or an ester-based solvent. After cleaning, any remaining rinse solution on the substrate and pattern can be removed. When ultrapure water is used, any remaining water on the substrate and pattern can be removed.

In addition, the developer may be used alone or in combination of two or more types.

As described above, after forming the resist pattern, a patterned wiring substrate can be obtained by etching. The etching method can be carried out using well-known methods such as dry etching with plasma gas, and wet etching with alkaline solutions, copper (II) chloride solutions, or iron (III) chloride solutions.

After forming the resist pattern, plating may also be performed. The plating method is not particularly limited, but examples include copper plating, solder plating, nickel plating, and gold plating.

The remaining resist pattern after etching may be stripped using an organic solvent. Examples of such organic solvents include, but are not limited to, PGMEA (propylene glycol monomethyl ether acetate), PGME (propylene glycol monomethyl ether), and EL (ethyl lactate). The stripping method is not particularly limited and may include, for example, immersion methods and spray methods. Additionally, the wiring substrate with the resist pattern formed may be a multilayer wiring substrate and may have small-diameter through holes.

In an embodiment, the wiring substrate is formed by depositing metal in a vacuum after forming the resist pattern, and then dissolving the resist pattern in a solution, a method known as the lift-off method.

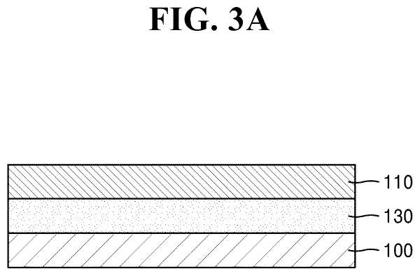

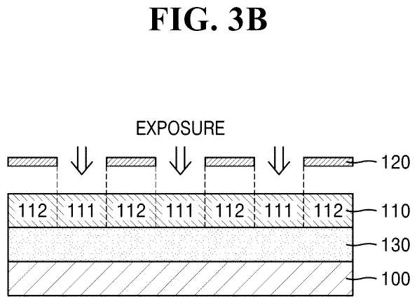

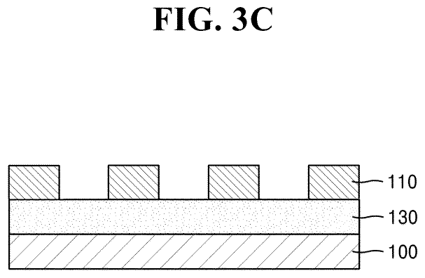

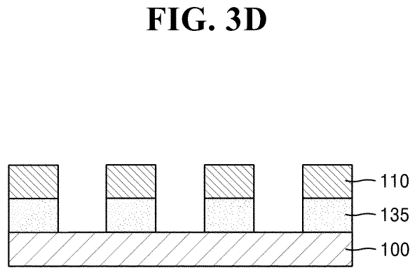

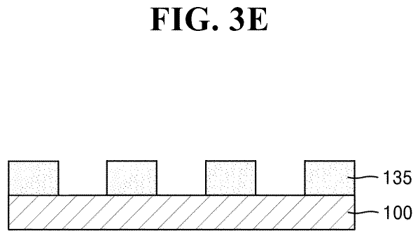

FIGS. 3A to 3E are side cross-sectional views showing a method of forming a patterning structure according to an embodiment.

As shown in FIG. 3A, a material layer 130 may be formed on the substrate 100 before forming the resist film 110 on the substrate 100. The resist film 110 may be formed on top of the material layer 130. The material layer 130 may include an insulating material (e.g., silicon oxide, silicon nitride), a semiconductor material (e.g., silicon), or a metal (e.g., copper). In some embodiments, the material layer 130 may have a multi-layer structure. The material of the material layer 130 may be different from the material of the substrate 100.

As shown in FIG. 3B, the resist film 110 can undergo a prebake process before exposure and then be exposed to high-energy rays through the mask 120, and subsequently the resist film 110 may include exposed region 111 and unexposed region 112.

As shown in FIG. 3C, the exposed resist film 110 may be developed using a developer. The exposed region 111 may be washed away by the developer, while the unexposed region 112 remains intact.

As shown in FIG. 3D, the resist pattern 110 can serve as a mask for etching the exposed portions of the material layer 130 to form the material pattern 135 on the substrate 100.

As shown in FIG. 3E, the resist pattern 110 can be removed.

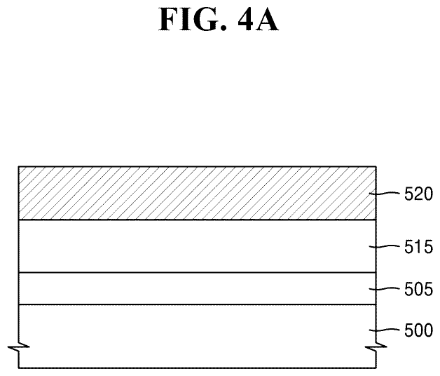

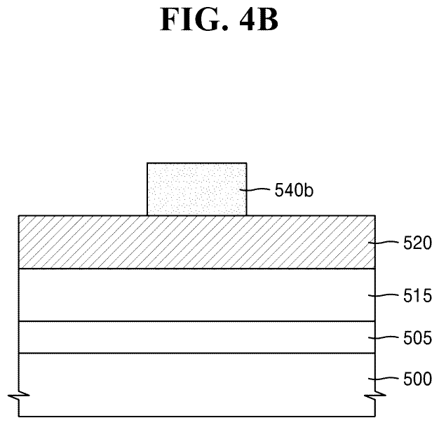

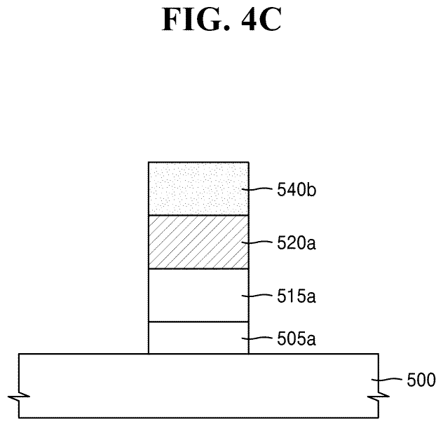

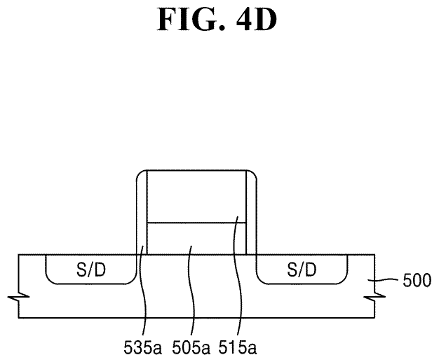

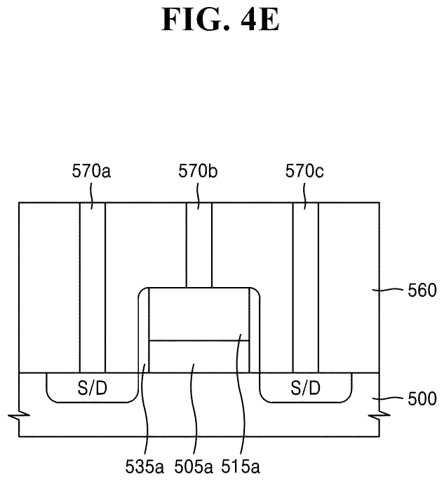

FIGS. 4A to 4E are side cross-sectional views showing a method of forming a semiconductor device according to an embodiment.

As shown in FIG. 4A, a gate dielectric 505 (e. g., silicon oxide) can be formed on the substrate 500. The substrate 500 may be a semiconductor substrate such as a silicon substrate. A gate layer 515 (e.g., doped polysilicon) may be formed on gate dielectric 505. A hardmask layer 520 may be formed on the gate layer 515.

As shown in FIG. 4B, a resist pattern 540b may be formed on the hardmask layer 520. The resist pattern 540b can be formed using a resist composition according to an embodiment. The resist composition may include an organic solvent.

As shown in FIG. 4C, the gate layer 515 and the gate dielectric 505 can be etched to form a hardmask pattern 520a, a gate electrode pattern 515a, and a gate dielectric pattern 505a.

As shown in FIG. 4D, the hard mask pattern 520a optionally may be removed and a spacer layer can be formed on the gate electrode pattern 515a and the gate dielectric pattern 505a. The spacer layer can be formed using a deposition process (e.g., CVD). The spacer layer can be etched to form spacers 535a (e.g., silicon nitride) on the sidewalls of the gate electrode pattern 515a and the gate dielectric pattern 505a. After forming the spacers 535a, ions can be implanted into the substrate 500 to form source/drain impurity regions (S/D).

As shown in FIG. 4E, an interlayer insulating film 560 (e.g., an oxide) can be formed on the substrate 500, covering the gate electrode pattern 515a, gate dielectric pattern 505a, and spacers 535a. Subsequently, the interlayer insulating film 560 can have electrical contacts 570a, 570b, and 570c formed to connect with the gate electrode 515a and the S/D regions. The electrical contacts 570a, 570b, and 570c can be formed of a conductive material (e.g., metal). Although not shown, a barrier layer can be formed between the sidewalls of the interlayer insulating film 560 and the electrical contacts 570a, 570b, and 570c.

FIGS. 4A to 4E show examples of forming transistors, but the disclosure is not limited thereto.

For example, although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on top of the gate electrode 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

The resist composition according to an embodiment can be used in the patterning process to form other types of semiconductor devices.

While the disclosure will be described in more detail using the following examples and comparative examples, the technical scope of the disclosure is not limited to these examples.

### EXAMPLES

### Synthesis Example 1: Synthesis of SM1

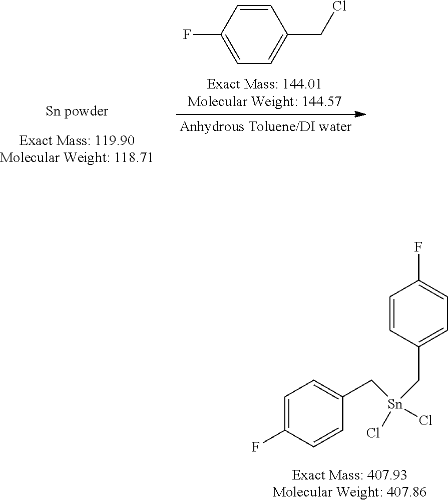 [SMILES: Fc1ccc(CCl)cc1 ; Fc1ccc([CH2][Sn]([Cl])([Cl])[CH2]c2ccc(F)cc2)cc1]

8.2 g (69.2 mmol) of Sn powder and 120 ml of dry toluene were placed in a 250 ml three-necked flask, and the temperature was raised to 90° C. After adding about 1.0 ml of DI water, 10.0 g (69.2 mmol) of 4-fluorobenzyl chloride was added dropwise over 10 minutes. The mixture was then heated to reflux at 130° C. with stirring for 4 hours, and the unreacted Sn powder was filtered off using a Buchner funnel. At the same time, as the filtered solution cooled, the product, a white crystalline SM1 precursor, was obtained in a yield of 6.5 g (36%).

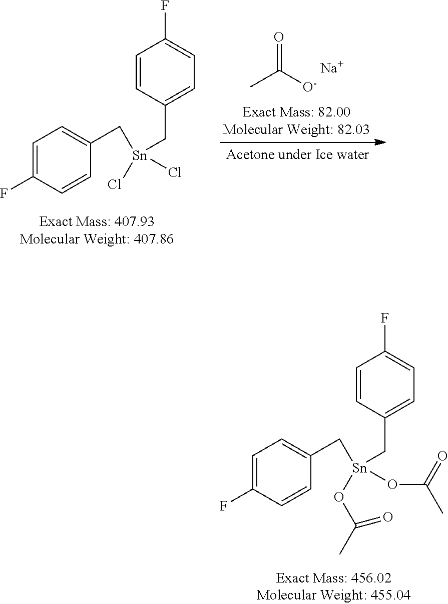

1.5 g (3.7 mmol) of SM1 precursor and 21.0 ml dry acetone were place in a 50 ml single-necked flask, and the temperature was lowered to 0° C. After adding 0.6 g (7.4 mmol) of sodium acetate, the mixture was stirred for about 12 hours. The NaCl salt formed in the solution was filtered using a 0.45 μm filter, and the filtered solution was then concentrated by rotary evaporation and dried under vacuum to yield 1.6 g of SM1 (74% yield).

¹H-NMR (500 MHz, DMSO-d₆): δ ˜6.9 (8H), ˜2.6 (4H), ˜1.6 (6H)

### Evaluation Example 1: Thin Film Phenomenon Evaluation

### (1) Terminology

In Examples 1-1 and 2-1 to 2-5, E₀ refers to the exposure dose at which the thin film is completely developed (no further reduction in thickness), while E₁ refers to the exposure dose at which the thin film begins to develop.

In Comparative Example 1-1, E₀ refers to the exposure dose at which the thin film begins to harden, and E₁ refers to the exposure dose at the saturation point where the film thickness no longer increases.

γ (gamma) is the value calculated using the contrast curve, according to the following Equation 1.

$$γ = {[ log ( \frac{{E}_{0}}{{E}_{1}} ) ]}^{- 1} \qquad 〈 Equation 1 〉$$

### (2) Thin Film Development Evaluation

SM1 obtained in Synthesis Example 1 was dissolved in cyclopentanone at a concentration of 2 wt %, and Compound A was added as an additive to this solution in a mass ratio of SM1: Compound A=2.5:1, resulting in Casting Solution C-1. Additionally, Casting Solution C-2 was prepared with the same composition as Casting Solution C-1, except that compound A was not added. Casting Solutions D-1 to D-5 were prepared with the same composition as Casting Solution C-1, except that the solvent listed in Table 2 below was used instead of cyclopentanone. A silicon wafer with a diameter of 4 inches was treated with O₂ plasma for 30 minutes, then Casting Solutions C-1, C-2, and D-1 to D-5 were spin-coated at 1200 rpm for 1 minute, followed by drying (PAB) at 90° C. for 1 minute to create films with the initial thickness shown in Table 1. Then a jig with a thickness of 3.5 mm and rectangular holes (1 cm×1 cm, arranged in a 4×4 grid) was placed on top of the films, each hole was exposed to DUV light (254 nm wavelength) with doses ranging from 0 mJ/cm² to 100 mJ/cm², and the films were dried (PEB) at 150° C. for 3 minutes. The dried films were immersed in a developer of PGME:PGMEA (99.5:0.5 v/v) at 25° C. for 60 seconds, and the remaining film thicknesses were measured and shown in Tables 1 and 2.

TABLE 1

| | | Organo- | | | initial | E₁ | E₀ | | |
|---|---|---|---|---|---|---|---|---|---|
| | casting | metallic | | | thickness | (mJ/ | (mJ/ | | |
| | solution | compound | additive | solvent | (nm) | cm²) | cm²) | γ | graph |
| Example 1-1 | C-1 | SM1 | Compound A | Cyclopentanone | 35.3 | 4.1 | 4.9 | 12.9 | 5A |
| Comparative | C-2 | SM1 | — | Cyclopentanone | 33.2 | 54.3 | 38.2 | −6.5 | 5B |
| Example 1-1 | | | | | | | | | |

TABLE 2

| | | Organo- | | | initial | E₁ | E₀ | | |
|---|---|---|---|---|---|---|---|---|---|
| | Casting | metallic | | | thickness | (mJ/ | (mJ/ | | |
| | solution | compound | additive | solvent | (nm) | cm²) | cm²) | γ | graph |
| Example 2-1 | D-1 | SM1 | Compound A | Methyl ethyl ketone | 34.4 | 2.9 | 5.9 | 3.2 | 6A |
| Example 2-2 | D-2 | SM1 | Compound A | Cyclohexanone | 31.9 | 4.4 | 9.1 | 3.2 | 6B |
| Example 2-3 | D-3 | SM1 | Compound A | Cycloheptanone | 31.3 | 6.3 | 10.6 | 4.4 | 6C |
| Example 2-4 | D-4 | SM1 | Compound A | γ-Butyrolactone | 34.5 | 4.6 | 7.6 | 4.6 | 6D |
| Example 2-5 | D-5 | SM1 | Compound A | n-butyl acetate | 32.9 | 4.3 | 10.3 | 2.6 | 6E |

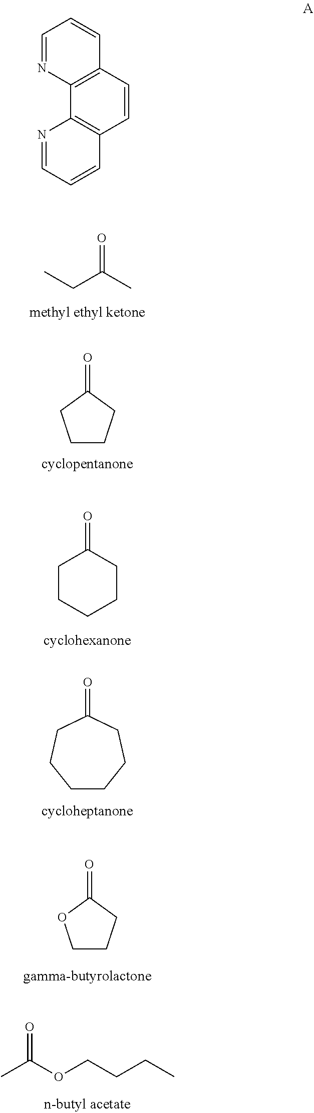

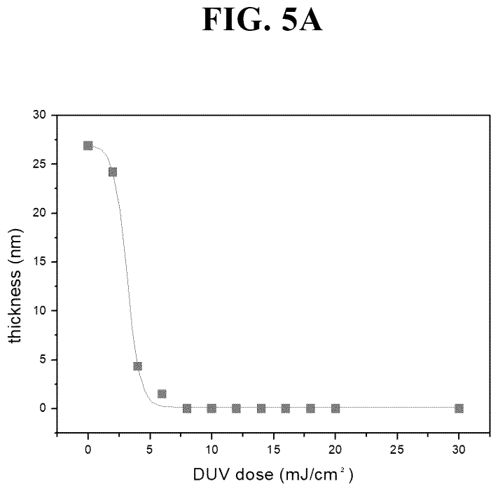

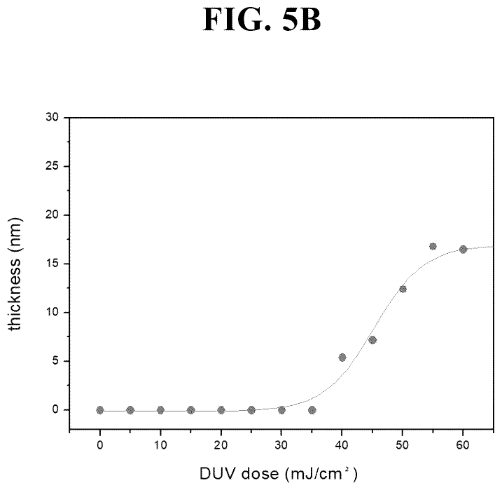

Referring to Table 1 and FIGS. 5A and 5B, it was confirmed that Example 1-1 exhibited the characteristics of a positive-type resist composition. In contrast, Comparative Example 1-1 did not undergo cross-linking under DUV exposure doses less than 30 mJ/cm², resulting in the entire thin film being washed away by the developer, but under DUV exposure doses greater than 30 mJ/cm², cross-linking occurred, and the thin film was not washed away by the developer, and consequently, it was confirmed that Comparative Example 1-1 exhibited the characteristics of a negative-type resist composition.

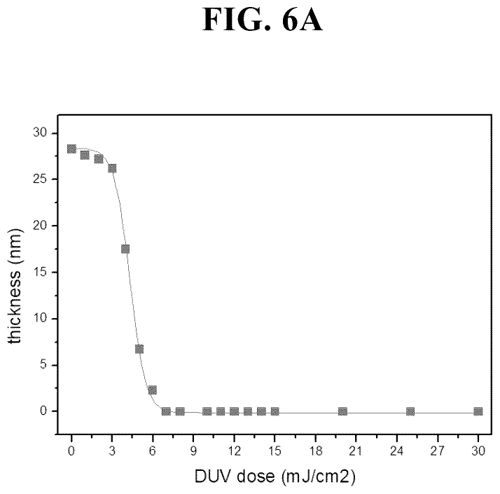

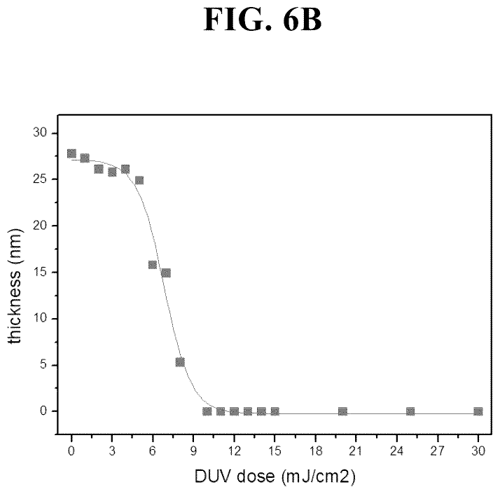

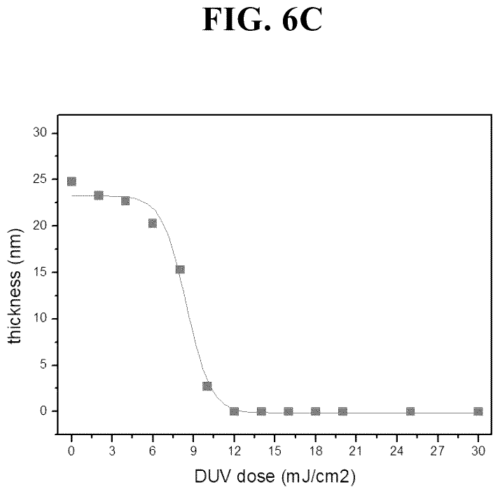

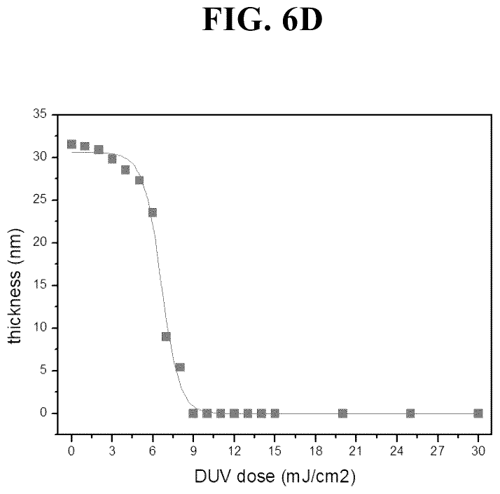

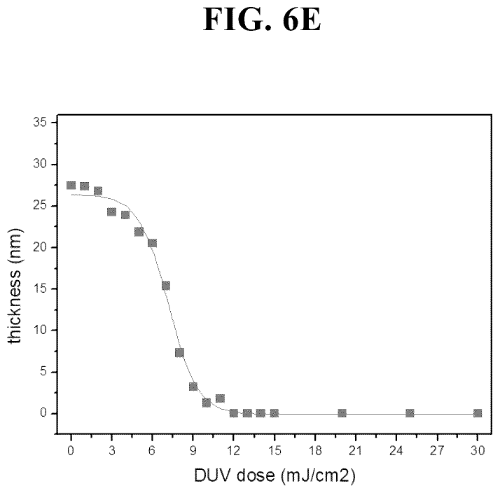

Referring to Table 2 and FIGS. 6A to 6E, it was confirmed that Examples 2-1 to 2-5 each exhibited the characteristics of a positive-type resist composition.

Embodiments of the disclosure can provide a resist composition with improved storage stability and enhanced sensitivity, offering patterns with improved resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A resist composition comprising:
an organometallic compound represented by any one of Formulae 1-1 to 1-4;
an additive represented by Formula 2; and
a solvent;
wherein the solvent comprises a non-polar solvent, a polar aprotic solvent, or a combination thereof, 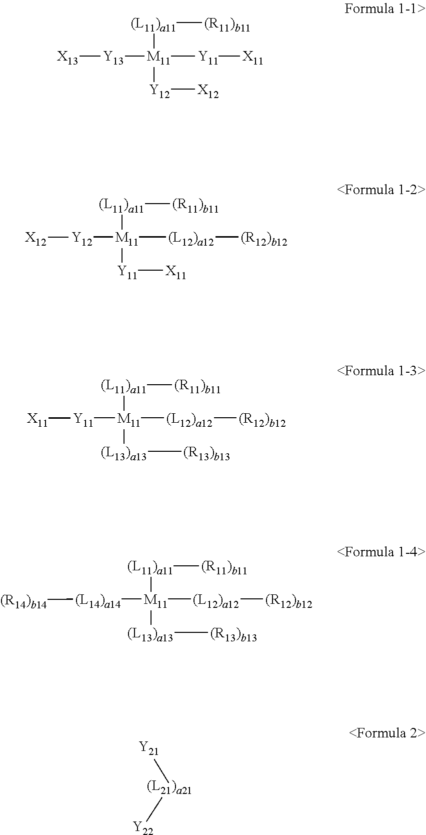
wherein, in Formulae 1-1 to 1-4 and 2,
M₁₁ is indium (In), tin (Sn), antimony (Sb), tellurium (Te), thallium (Tl), lead (Pb), bismuth (Bi), or polonium (Po),
L₁₁ to L₁₄ are each independently a single bond or a linear, branched or cyclic C₁-C₃₀ divalent hydrocarbon group,
a11 to a14 are each independently selected from integers of 1 to 4,
R₁₁ to R₁₄ are each independently a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or an unsubstituted C₇-C₃₀ arylalkyl group, a substituted or unsubstituted C₁-C₃₀ heteroaryl group, or a substituted or unsubstituted C₂-C₃₀ heteroarylalkyl group,
an adjacent two of R₁₁ to R₁₄ are optionally bonded to each other to form a condensed ring,
b11 to b14 are each independently selected from integers of 1 to 4,
Y₁₁ to Y₁₃ are each independently O, O(C═O), S, S(C═O), NX₁₄ or N(C═O),
X₁₁ to X₁₄ are each independently hydrogen, deuterium, or a linear, branched, or cyclic C₁-C₃₀ monovalent hydrocarbon group optionally including a heteroatom,
Y₂₁ and Y₂₂ are each independently a linear, branched or cyclic C₁-C₃₀ monovalent hydrocarbon group including as a heteroatom at least one selected from the group consisting of an oxygen atom, a sulfur atom, a nitrogen atom, and a phosphorus atom,
L₂₁ is a single bond, a double bond, or a linear, branched, or cyclic C₁-C₃₀ divalent hydrocarbon group,
each a21 is independently selected from integers of 1 to 4, and
an adjacent two of Y₂₁, Y₂₂ and L₂₁ are optionally bonded to each other to form a condensed ring.

2. The resist composition of claim 1,
wherein M₁₁ is In, Sn or Sb.

3. The resist composition of claim 1,
wherein R₁₁ to R₁₄ are each independently selected from a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

4. The resist composition of claim 1,
the organometallic compound is represented by one of Formulae 1-1 to 1-3,
wherein Y₁₁ to Y₁₃ are each independently O, O(C═O), S, or S(C═O), and
X₁₁ to X₁₄ are each independently selected from: hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

5. The resist composition of claim 1,
wherein the organometallic compound represented by any one of Formulae 1-1 to 1-4 is selected from Group I below: 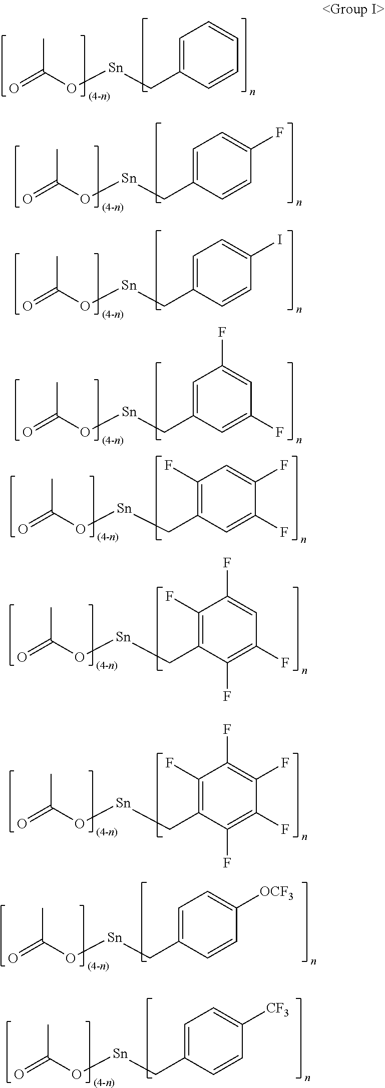 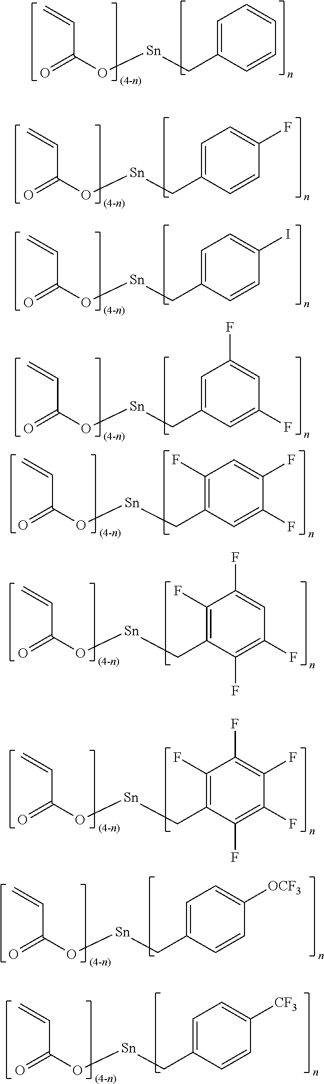 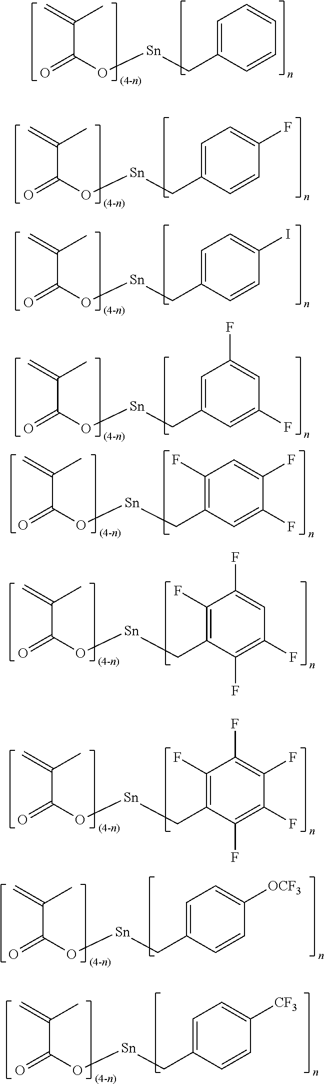
wherein, in Group I, n is an integer from 1 to 4.

6. The resist composition of claim 1,
wherein Y₂₁ is represented by any one of Formulae 4-1 to 4-5, and
Y₂₂ is represented by any one of Formulae 4-6 to 4-10: 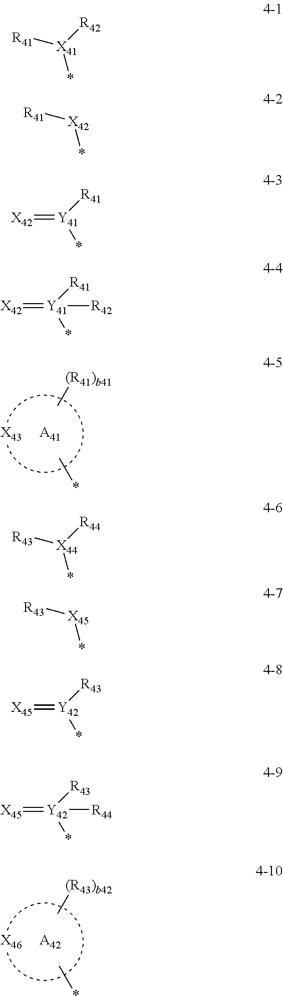
wherein, in Formulae 4-1 to 4-10,
X₄₁ and X₄₄ are each independently N or P,
X₄₂ and X₄₅ are each independently O or S,
X₄₃ and X₄₆ are each independently O, S, N or P,
Y₄₁ and Y₄₂ are each independently C, S or P,
A₄₁ is a C₁-C₃₀ heterocyclic group containing X₄₃ as a ring member,
A₄₂ is a C₁-C₃₀ heterocyclic group containing X₄₆ as a ring member,
R₄₁ to R₄₄ are each independently hydrogen, deuterium, a halogen, a cyano group, a nitro group, a hydroxyl group, a thiol group, an amino group, a carboxylate group, or a linear, branched or cyclic C₁-C₃₀ divalent hydrocarbon group,
b41 and b42 are each independently selected from integers from 1 to 10, and
* is a bonding site with a neighboring atom.

7. The resist composition of claim 6,
wherein A₄₁ and A₄₂ are each independently a monovalent group derived from a first ring, a monovalent group derived from a condensed ring in which two or more of the first ring are condensed with each other, or a monovalent group derived from a condensed ring in which one or more of the first ring and one or more second rings are condensed with each other;
the first ring is tetrahydropyran, dihydropyran, pyrane, tetrahydrothiopyrane, dihydrothiopyrane, thiopyrane, tetrahydrofurane, dihydrofurane, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine or triazine; and
the second rings are cyclopentane, cyclopentadiene, cyclohexane, cyclohexene, cyclohexadiene, benzene, or naphthalene.

8. The resist composition of claim 1,
wherein the additive is represented by the following Formula 2-1: 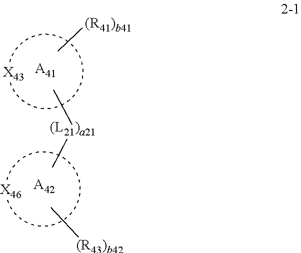
wherein, in Formula 2-1,
X₄₃ and X₄₆ are each independently O, S, N or P,
A₄₁ is a C₁-C₃₀ heterocyclic group containing X₄₃ as a ring member,
A₄₂ is a C₁-C₃₀ heterocyclic group containing X₄₆ as a ring member,
L₂₁ is a single bond, a double bond, or a linear, branched, or cyclic C₁-C₃₀ divalent hydrocarbon group,
a21 is an integer from 1 to 4,
R₄₁ and R₄₃ are each independently a linear, branched or cyclic C₁-C₃₀ divalent hydrocarbon group,
b41 and b42 are each independently selected from integers from 1 to 10, and
an adjacent two of R₄₁, R₄₃ and L₂₁ are optionally bonded to each other to form a condensed ring.

9. The resist composition of claim 1,
wherein the additive is represented by any one of Formulae 2-21 to 2-26 below: 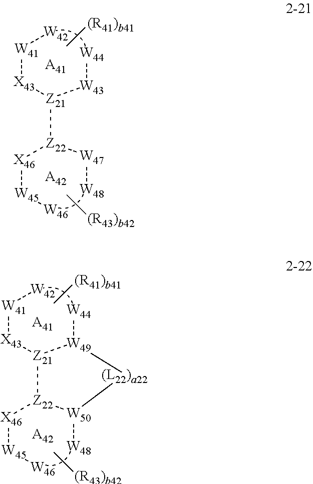 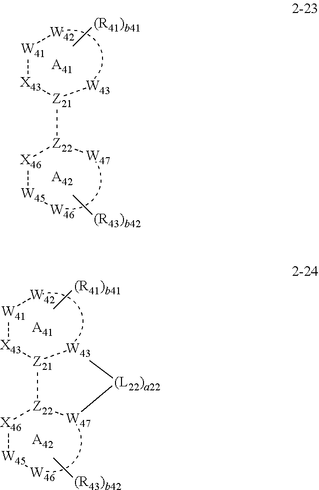 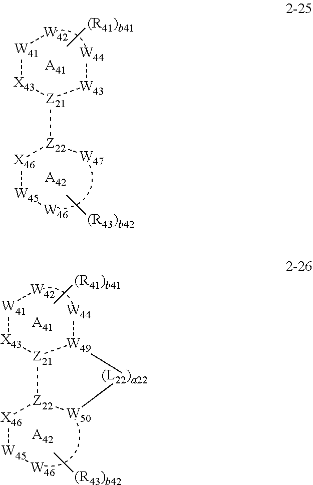
wherein, in Formulae 2-21 to 2-26,
X₄₃ and X₄₆ are each independently O, S, N or P,
A₄₁ is a C₁-C₃₀ heterocyclic group containing, as ring members, Z₂₁, X₄₃, W₄₁ to W₄₂, and one or two selected from W₄₃, W₄₄, and W₄₉,
A₄₂ is a C₁-C₃₀ heterocyclic group containing, as ring members, Z₂₂, X₄₆, W₄₅ to W₄₆ and one or two selected W₄₇, W₄₈, and W₅₀,
Z₂₁ and Z₂₂ are each independently C or N,
W₄₁ to W₅₀ are each independently C(R₄₁ₐ), C(R₄₁ₐ)(R_{41b}), C(R₄₃ₐ), C(R₄₃ₐ)(R_{43b}), or N,
bonds between Z₂₁ and Z₂₂, between Z₂₁ and X₄₃, between X₄₃ and W₄₁, between W₄₁ and W₄₂, between Z₂₁ and W₄₃, between W₄₃ and W₄₄, between Z₂₂ and W₄₆, between W₄₆ and W₄₅, between W₄₅ and W₄₆, between Z₂₂ and W₄₇, between W₄₇ and W₄₈, between W₄₄ and W₄₉, between W₄₉ and Z₂₁, between Z₂₂ and W₅₀, between W₄₈ and W₅₀, between W₄₂ and W₄₃, between W₄₆ and W₄₇, between W₄₂ and W₄₉, and between W₄₆ and W₅₀ are each either a single bond or a double bond;
L₂₂ is selected from: a single bond; a double bond; and a C₁-C₃₀ alkylene group and a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or a combination thereof,
a22 is selected from integers 1 to 4,
R₄₁, R₄₃, R₄₁ₐ, R_{41b}, R₄₃ₐ and R_{43b} are each independently a linear, branched or cyclic C₁-C₃₀ divalent hydrocarbon group; and
b41 and b42 are each independently selected from integers from 1 to 10.

10. The resist composition of claim 1,
wherein the additive is selected from Group II below:

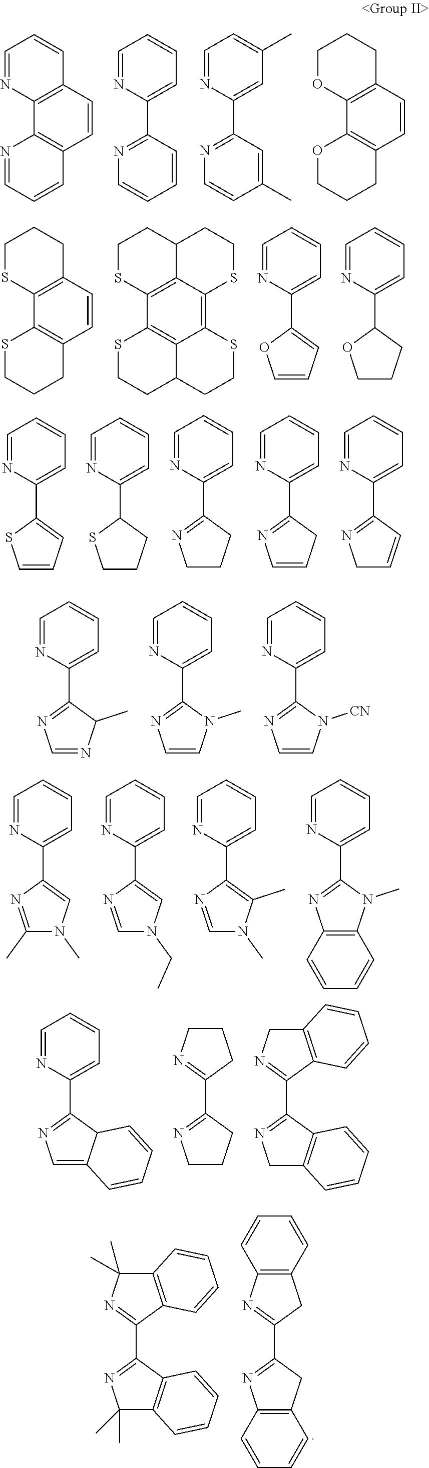

11. The resist composition of claim 1,
wherein the additive is included in an amount of about 0.1 parts by weight to about 100,000 parts by weight, based on 100 parts by weight of the organometallic compound.

12. The resist composition of claim 1,
wherein the solvent comprises the polar aprotic solvent.

13. The resist composition of claim 1,
wherein the solvent is selected from ketone-based solvents, ester-based solvents, and a combination thereof.

14. The resist composition of claim 1,
wherein the solvent is selected from linear ketone solvents, cyclic ketone solvents, polyhydric alcohol-containing ethercarboxylate solvents, lactone solvents, acetate ester solvents, and a combination thereof.

15. The resist composition of claim 1,
wherein the solvent is selected from methyl ethyl ketone, cyclopentanone, cyclohexanone, cycloheptanone, propylene glycol monomethyl ether acetate, γ-butyrolactone, δ-valerolactone, n-butyl acetate, and a combination thereof.

16. The resist composition of claim 1, wherein
the resist composition is substantially free of photoacid generators.

17. A method of forming a pattern, the method comprising:
applying the resist composition of claim 1 to form a resist film;
exposing at least a portion of the resist film to high-energy rays to provide an exposed resist film; and
developing the exposed resist film using a developer.

18. The method of claim 1,
wherein the exposing the at least a portion of the resist film is performed by at least one of irradiating deep ultraviolet rays (DUV), extreme ultraviolet rays (EUV), or electron beams (EBs).

19. The method of claim 17,
wherein the organometallic compound is decomposed by the exposing at least a portion of the resist film.

20. The method of claim 17,
wherein the exposed resist film includes an exposed portion and a non-exposed portion, and
wherein, in the developing the exposed resist film, the exposed portion is removed.
